(19) United States
(12) Patent Application Publication
(10) Pub. No.: US 2025/0239577 A1
(43) Pub. Date: Jul. 24, 2025

(54) CHIP STRUCTURE INCLUDING OPTICAL INTEGRATED CIRCUIT CHIP, AND SEMICONDUCTOR PACKAGE INCLUDING THE SAME

(71) Applicant: Samsung Electronics Co., Ltd., Suwon-si (KR)

(72) Inventors: Juhyeon Oh, Suwon-si (KR); Seokgeun Ahn, Suwon-si (KR); Daeho Lee, Suwon-si (KR)

(21) Appl. No.: 19/026,803

(22) Filed: Jan. 17, 2025

(30) Foreign Application Priority Data
Jan. 22, 2024 (KR) 10-2024-0009795

(51) Int. Cl. H01L 25/16; G02B 6/42; H01L 23/00; H01L 23/31; H05K 1/18; H10D 80/30

(52) U.S. Cl. CPC H01L 25/167; G02B 6/4212; G02B 6/4214; G02B 6/4243; G02B 6/4262; H01L 23/3185; G02B 6/4239; H01L 24/08; H01L 24/80; H01L 2224/08145; H01L 2224/80203; H01L 2224/80895; H01L 2224/80896; H01L 2924/146; H05K 1/181; H10D 80/30

(57) ABSTRACT

A chip structure includes an optical integrated circuit chip including a first waveguide extending in a horizontal direction and an optical guide unit, an electronic integrated circuit chip on the optical integrated circuit chip, and a connector above the optical integrated circuit chip and including a body, a second waveguide extending from an upper surface to a lower surface of the body, and an engagement groove extending inward from the upper surface of the body, wherein the first waveguide includes an edge coupler located at an end adjacent to the optical guide unit among both ends of the first waveguide, and the optical guide unit is configured to transfer signals between the first waveguide and the second waveguide.

### CROSS-REFERENCE TO RELATED APPLICATION

This application is based on and claims priority under 35 U.S.C. § 119 to Korean Patent Application No. 10-2024-0009795, filed on Jan. 22, 2024, in the Korean Intellectual Property Office, the disclosure of which is incorporated by reference herein in its entirety.

### BACKGROUND

The inventive concept relates to a semiconductor package and a manufacturing method thereof, and more particularly, to a chip structure including an optical integrated circuit chip and a semiconductor package including the same.

More and more are taking advantage of semiconductor packages in improving the functionality of electronic devices and integrating components. A semiconductor package enables various integrated circuits, such as memory chips or logic chips, to be mounted on a package substrate. In a recent environment where data traffic is increasing in data centers and communication infrastructure, studies of the semiconductor packages including optical integrated circuits continue.

### SUMMARY

Aspects of the inventive concept provide a chip structure in which an optical fiber is detachably coupled, and a semiconductor package including the same.

However, the objects of the inventive concept are not limited to the aforementioned object, but other objects not described herein will be clearly understood by those skilled in the art from the following description.

According to an aspect of the inventive concept, a chip structure includes an optical integrated circuit chip including a first waveguide extending in a horizontal direction and an optical guide unit, an electronic integrated circuit chip on the optical integrated circuit chip, and a connector above the optical integrated circuit chip and including a body, a second waveguide extending from an upper surface to a lower surface of the body, and an engagement groove extending inward from the upper surface of the body, wherein the first waveguide includes an edge coupler located at an end adjacent to the optical guide unit among both ends of the first waveguide, and the optical guide unit is configured to transfer signals between the first waveguide and the second waveguide.

According to another aspect of the inventive concept, a chip structure includes an optical integrated circuit chip including a first waveguide extending in a horizontal direction, an electronic integrated circuit chip on the optical integrated circuit chip, a connector above the optical integrated circuit chip and including a body, a second waveguide extending from an upper surface to a lower surface of the body, and an engagement groove extending inward from the upper surface of the body, a molding layer above the optical integrated circuit chip and surrounding the electronic integrated circuit chip and the connector, and a polishing stop film between the molding layer and the connector, between the molding layer and the electronic integrated circuit chip, and between the molding layer and the optical integrated circuit chip.

According to another aspect of the inventive concept, a semiconductor package includes a package substrate, a semiconductor chip on the package substrate, a chip structure on the package substrate and including an optical integrated circuit chip, an electronic integrated circuit chip located on the optical integrated circuit chip, and a connector above the optical integrated circuit chip, and an optical fiber module including a frame formed to be detachably coupled to the connector of the chip structure and an optical fiber attached to the frame, wherein the optical integrated circuit chip of the chip structure includes a first waveguide extending in a horizontal direction on an upper surface of the optical integrated circuit chip, and the connector of the chip structure further includes a second waveguide extending in a vertical direction.

### BRIEF DESCRIPTION OF THE DRAWINGS

Embodiments will be more clearly understood from the following detailed description taken in conjunction with the accompanying drawings in which:

FIG. 1 is a plan view schematically illustrating a semiconductor package according to an embodiment;

FIG. 2 is a plan view schematically illustrating a chip structure according to an embodiment;

FIG. 3 is a cross-sectional view schematically illustrating the chip structure of FIG. 2 and an optical fiber module coupled to the chip structure taken along line A-A′ of FIG. 2;

FIG. 4 is an enlarged view schematically illustrating a region EX1 of the chip structure of FIG. 3;

FIG. 5 is an enlarged view schematically illustrating a region EX2 of the chip structure and the optical fiber module of FIG. 3;

FIG. 6 is an enlarged view schematically illustrating a portion of a chip structure according to an embodiment;

FIG. 7 is an enlarged view schematically illustrating a portion of a chip structure according to an embodiment;

FIG. 8 is an enlarged view schematically illustrating a portion of a chip structure and an optical fiber module according to an embodiment;

FIG. 9 is an enlarged view schematically illustrating a portion of a chip structure and an optical fiber module according to an embodiment; and

FIGS. 10 to 18 are diagrams sequentially illustrating a manufacturing method of a chip structure according to an embodiment.

### DETAILED DESCRIPTION OF THE EMBODIMENTS

The embodiments may have diverse changes and various forms, and thus, some embodiments are illustrated in the drawings and described in detail. However, is the description herein is not intended to limit the embodiments to some specific embodiments.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Terms such as “same,” “equal,” “planar,” “coplanar,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

Items described in the singular herein may be provided in plural, as can be seen, for example, in the drawings. Thus, the description of a single item that is provided in plural should be understood to be applicable to the remaining plurality of items unless context indicates otherwise.

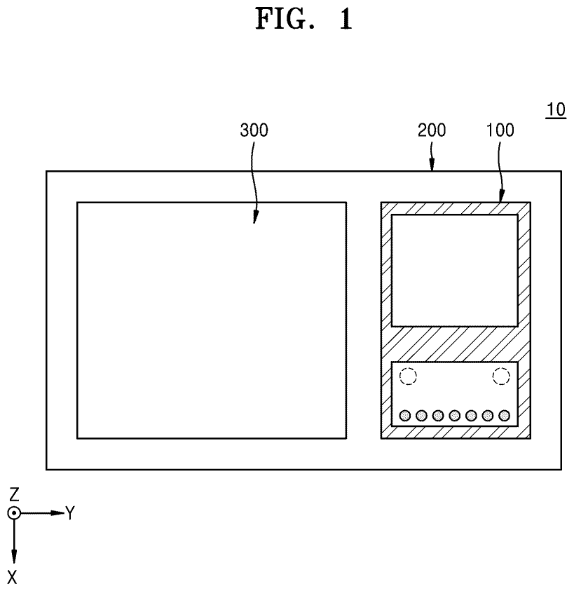

FIG. 1 is a plan view schematically illustrating a semiconductor package 10 according to an embodiment.

Referring to FIG. 1, the semiconductor package 10 may include a package substrate 200, a semiconductor chip 300, and a chip structure 100. The semiconductor package 10 may include a semiconductor package communicating with external devices through optical signals.

Unless specifically defined or used in a different context below, a direction parallel to an upper surface of the package substrate 200 is described as a first horizontal direction (X direction), a direction perpendicular to the upper surface of the package substrate 200 is described as a vertical direction (Z direction), and a direction perpendicular to the first horizontal direction (X direction) and the vertical direction (Z direction) is described as a second horizontal direction (Y direction). The first horizontal direction (X direction) and the second horizontal direction (Y direction) are collectively described as a horizontal direction.

The package substrate 200 may be an interposer including a substrate and a through-via passing through the substrate. For example, the package substrate 200 may be a glass interposer in which the substrate includes glass and the through-via includes a through glass via (TGV). However, the embodiments are not limited thereto. The package substrate 200 may be a silicon interposer in which the substrate includes silicon and the through-via includes a through silicon via (TSV). A through via that passes electrical signals therethrough may be described herein as a conductive through via.

In some embodiments, the package substrate 200 may be a redistribution structure including a redistribution pattern and a redistribution insulating layer surrounding the redistribution pattern.

The redistribution insulating layer may include an insulating material, for example, photo imageable dielectric (PID) resin. In some embodiments, the redistribution insulating layer may further include an inorganic filler. In some embodiments, the redistribution insulating layer may have a multilayer structure in which the redistribution pattern is disposed on each layer.

The redistribution pattern may include a redistribution line pattern (e.g., redistribution lines) extending in the horizontal direction and a redistribution via pattern (e.g., redistribution vias) extending in the vertical direction (Z direction) from the redistribution line pattern. The redistribution line pattern may be arranged on at least one of upper and lower surfaces of the redistribution insulating layer or in the redistribution insulating layer. The redistribution via pattern may pass through the redistribution insulating layer and be connected to a portion of the redistribution line pattern.

The redistribution pattern may include a conductive material, for example, copper (Cu), aluminum (Al), silver (Ag), tin (Sn), gold (Au), nickel (Ni), palladium (Pb), titanium (Ti), or alloy thereof.

In some embodiments, the package substrate 200 may be a printed circuit board (PCB) including a core insulating layer including at least one material selected from among phenolic resin, epoxy resin, and polyimide.

The semiconductor chip 300 may be located on the package substrate 200. The semiconductor chip 300 may include an active surface and an inactive surface opposite thereto. In some embodiments, the semiconductor chip 300 may include an application specific integrated circuit (ASIC).

In some embodiments, the semiconductor chip 300 may be mounted on the package substrate 200 such that the active surface thereof faces down. Connection pads of the semiconductor chip 300 may be located on the active surface and the semiconductor chip 300 may be mounted on the package substrate 200 such that the connection pads of the semiconductor chip 300 are electrically connected to upper pads of the package substrate 200.

In some embodiments, various types of a plurality of individual devices may be located on the active surface of the semiconductor chip 300. For example, the plurality of individual devices may include various microelectronic devices, for example, complementary metal-oxide semiconductor (CMOS) transistors, metal-oxide-semiconductor filed effect transistors (MOSFET), system large scale integration (LSI), image sensors such as CMOS imaging sensors (CIS), micro-electro-mechanical systems (MEMS), active elements, passive elements, and the like.

The chip structure 100 may be located on the package substrate 200. The chip structure 100 may be spaced apart from the semiconductor chip 300 in the horizontal direction. The chip structure 100 may be electrically connected to the semiconductor chip 300 through the package substrate 200.

For example, the chip structure 100 may receive an optical signal from an external device, convert the received optical signal into an electric signal, and then input the electric signal into the semiconductor chip 300 through the package substrate 200. The chip structure 100 may be described as an optical-electrical chip.

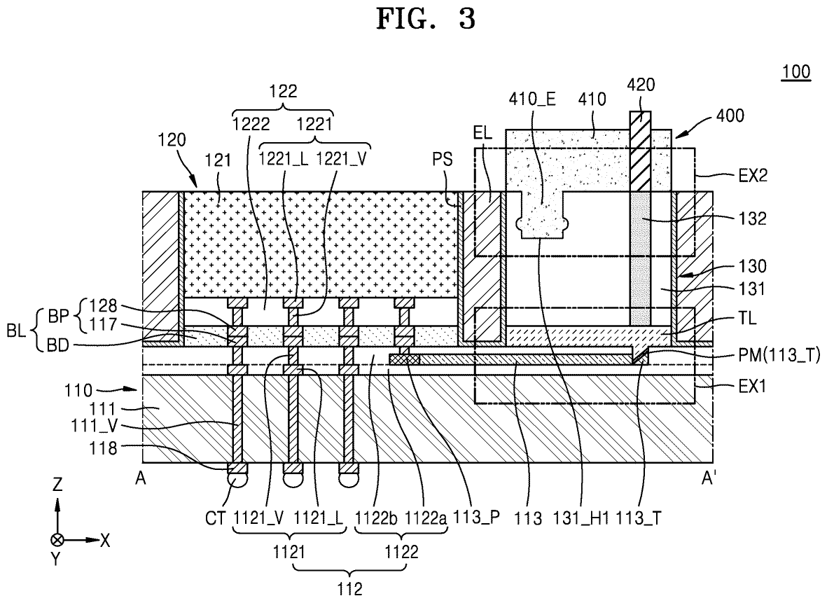

The chip structure 100 may be detachably coupled to an optical fiber module 400 (see FIG. 3), which in some embodiments is not considered to be part of an optical-electrical chip that forms a chip structure 100 (e.g., the label “400” in FIG. 3 may not be included as part of the chip structure 100). The chip structure 100 is described in more detail below.

Since the semiconductor package 10 may communicate with an external device with an optical signal through the chip structure 100, the data processing speed of the semiconductor package 10 may increase. In addition, since the optical fiber module 400 (see FIG. 3) is able to be detached from the chip structure 100 of the semiconductor package 10, the optical fiber may be replaced in the semiconductor package 10 when a failure occurs in an optical fiber.

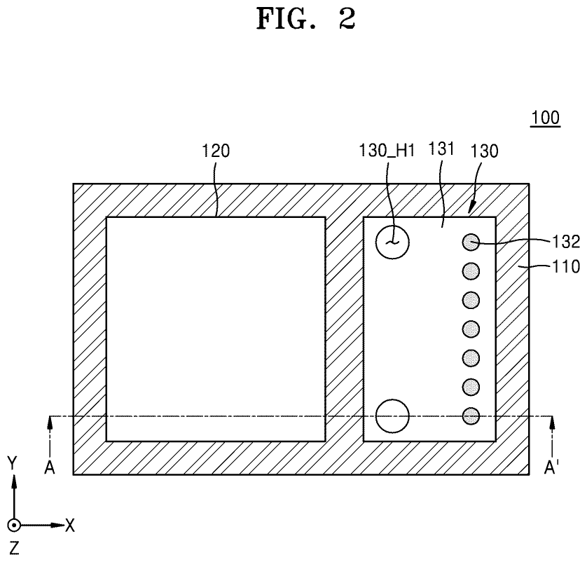

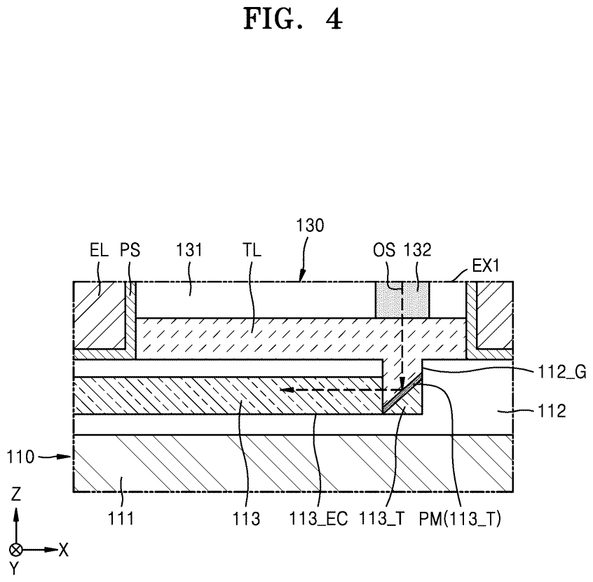

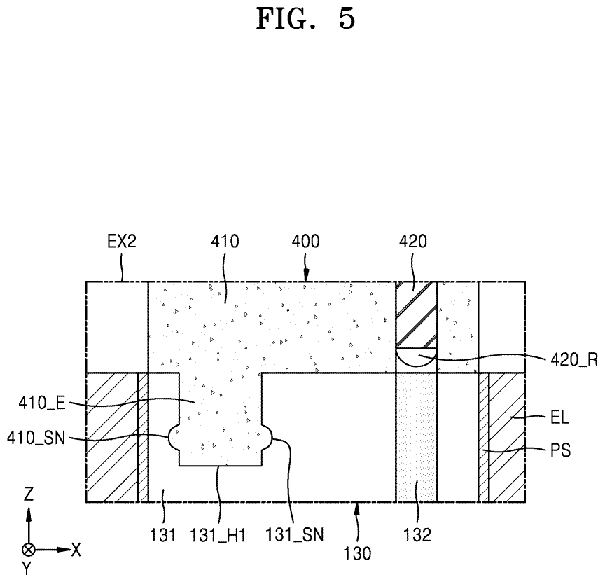

FIG. 2 is a plan view schematically illustrating the chip structure 100 according to an embodiment. FIG. 3 is a cross-sectional view schematically illustrating the chip structure 100 of FIG. 2 and the optical fiber module 400 coupled to the chip structure 100 taken along line A-A′ of FIG. 2. FIG. 4 is an enlarged view schematically illustrating a region EX1 of the chip structure 100 of FIG. 3. FIG. 5 is an enlarged view schematically illustrating a region EX2 of the optical fiber module 400 and the chip structure 100 of FIG. 3.

Referring to FIGS. 2 to 5, the chip structure 100 may include a photonic integrated circuit (PIC) chip 110, an electronic integrated circuit (EIC) chip 120, and a connector 130. For example, the optical fiber module 400 may be detachably coupled to the connector 130 of the chip structure 100.

The PIC chip 110 may be located on the package substrate 200 (see FIG. 1). The PIC chip 110 may be spaced apart from the semiconductor chip 300 (see FIG. 1) in the horizontal direction.

Lower pads 118 of the PIC chip 110 may be electrically connected to upper pads of the package substrate 200 through connection terminals CT. However, a connection method between the PIC chip 110 and the package substrate 200 is not limited thereto.

The PIC chip 110 may include a first substrate 111, a first wiring structure 112, a first waveguide 113, and an optical guide unit 113_T. For example, the first wiring structure 112 and the first waveguide 113 may be located on an upper surface of the first substrate 111. For example, the first substrate 111 may include first through-vias 111_V extending from the upper surface to a lower surface thereof. The first through-vias 111_V may be electrically connected to the first wiring structure 112.

In some embodiments, the first substrate 111 may include a semiconductor material such as silicon (Si). Alternatively, the first substrate 111 may include a semiconductor material such as germanium (Ge).

The first wiring structure 112 may include a first wiring pattern 1121 and a first wiring insulating layer 1122 surrounding the first wiring pattern 1121. The first wiring pattern 1121 may include first wiring lines 1121_L extending in the horizontal direction and first wiring vias 1121_V extending from the first wiring lines 1121_L in the vertical direction (Z direction). The first wiring pattern 1121 may be electrically connected to the first through-vias 111_V.

The first wiring insulating layer 1122 may be divided into an upper wiring insulating layer 1122b and a lower wiring insulating layer 1122a. In some embodiments, the upper wiring insulating layer 1122b may include an oxide layer such as silicon oxide. The lower wiring insulating layer 1122a may include a dielectric layer including at least one layer of silicon oxide, silicon nitride, and a combination thereof. In some embodiments, the upper wiring insulating layer 1122b and the lower wiring insulating layer 1122a may include the same component.

The PIC chip 110 may further include upper pads 117. The upper pads 117 may be located on an upper surface of the first wiring structure 112 and electrically connected to the first wiring pattern 1121. The upper pads 117 may be electrically conductive terminals configured to receive and transmit electrical signals therethrough.

The first waveguide 113 may include a patterned silicon layer and may extend in the horizontal direction on the upper wiring insulating layer 1122b. For example, the first waveguide 113 may be buried in the first wiring insulating layer 1122. For example, the first waveguide 113 may be located on the upper wiring insulating layer 1122b and covered by the lower wiring insulating layer 1122a.

In some embodiments, the first waveguide 113 may include a silicon waveguide including silicon and the first wiring insulating layer 1122 may include a buried oxide (BOX) layer. However, the embodiments are not limited thereto. The first waveguide 113 may be covered by an oxide layer distinct from the first wiring insulating layer 1122 in some embodiments.

In some embodiments, the first waveguide 113 may further include an edge coupler 113_EC. The edge coupler 113_EC may be located at an end adjacent to the optical guide unit 113_T among both ends of the first waveguide 113.

The first waveguide 113 may be connected to an optical component 113_P. The optical component 113_P may convert an optical signal OS into an electric signal and an electric signal into an optical signal OS. In some embodiments, the optical component 113_P may include an optical detector, laser diode, and modulator.

In a process of inputting the optical signal into the chip structure 100, the optical detector may detect the optical signal OS input into the PIC chip 110. The PIC chip 110 may detect the input optical signal OS through the optical detector and convert the input optical signal OS into an electric signal.

In a process during which the chip structure 100 outputs the optical signal OS, the EIC chip 120 may transmit the electric signal to the modulator. The modulator may convert the electric signal into the optical signal OS by inputting a value corresponding to the received electric signal into light emitted by the laser diode.

The optical guide unit 113_T may adjust a path of the optical signal OS by reflecting and/or refracting the optical signal OS. The optical guide unit 113_T may allow the first waveguide 113 and the second waveguide 132 to transmit the optical signal OS to each other. The optical guide unit 113_T may be described as a waveguide connector or an inter-waveguide router, and may be configured to transfer signals (e.g., optical signals) between the second waveguide 132 and the first waveguide 113.

For example, the optical guide unit 113_T may be located on one side (e.g., in the horizontal direction) of the first waveguide 113 and is configured to transmit the optical signal OS incident from the second waveguide 132 toward the optical guide unit 113_T to the edge coupler 113_EC of the first waveguide 113.

According to this embodiment, the first waveguide 113 may have the edge coupler 113_EC but the edge coupler 113_EC may not be located on a straight line with an optical fiber 420 in the horizontal direction. As illustrated in FIG. 3, the optical fiber 420 may transmit/receive the optical signal OS in a direction perpendicular to the extension direction of the first waveguide 113. Since the path of the optical signal OS is adjusted by the optical guide unit 113_T, the optical signal OS emitted from the optical fiber 420 may be input into the edge coupler 113_EC of the first waveguide 113.

In some embodiments, the optical guide unit 113_T may include at least one mirror PM. Although the optical guide unit 113_T is illustrated to have one mirror PM in FIG. 4, the number of mirrors PM included in the optical guide unit 113_T is not limited thereto.

The at least one mirror PM may be positioned such that the optical signal OS output from one waveguide between the first waveguide 113 and the second waveguide 132 is reflected according to reflection law and then incident to the other waveguide. For example, the optical signal OS incident from one waveguide between the first waveguide 113 and the second waveguide 132 to the optical guide unit 113_T may be reflected on the at least one mirror PM and then be incident to the other waveguide. For example, the optical signal OS incident from the second waveguide 132 to the optical guide unit 113_T may be reflected and then incident to the edge coupler 113_EC of the first waveguide 113.

In some embodiments, the first wiring structure 112 may further include a groove 112_G extending inward from an upper surface of the first wiring insulating layer 1122. For example, the groove 112_G of the first wiring structure 112 may be located above the optical guide unit 113_T. A transparent adhesive layer TL may be disposed in the groove 112_G of the first wiring structure 112.

In some embodiments, a component of the at least one mirror PM may be substantially the same as a component of the first waveguide 113. For example, the at least one mirror PM may be formed by etching a portion of the first waveguide 113 through a photolithography process and performing a nanoimprint process to a surface of the etched portion of the first waveguide 113. However, the embodiments are not limited thereto. The at least one mirror PM may be formed by removing a portion of the first wiring insulating layer 1122 and performing the nanoimprint process to a surface of the portion of the first wiring insulating layer 1122.

The EIC chip 120 may be located on the PIC chip 110. The EIC chip 120 may interconnect the PIC chip 110 with the semiconductor chip 300 (see FIG. 1). For example, the EIC chip 120 may convert the electric signal converted by the PIC chip 110 to match the electric signal with the semiconductor chip 300 (see FIG. 1).

In some embodiments, a width of the EIC chip 120 (e.g., in one or both of the X or Y horizontal directions) may be less than a width of the PIC chip 110. For example, side surfaces of the EIC chip 120 may be located on an upper surface of the PIC chip 110. A portion of the PIC chip 110 may not be covered by the EIC chip 120.

The EIC chip 120 may include a second substrate 121 and a second wiring structure 122. The second substrate 121 of the EIC chip 120 may include an active surface and an inactive surface opposite thereto. The second wiring structure 122 may be formed on the active surface of the second substrate 121.

The second substrate 121 may include a semiconductor material such as silicon (Si). Alternatively, the second substrate 121 may include a semiconductor material such as germanium (Ge).

In some embodiments, the EIC chip 120 may include a plurality of individual devices used in interfacing with the PIC chip 110. The plurality of individual devices of the EIC chip 120 may be located on the active surface of the second substrate 121. For example, the EIC chip 120 may include CMOS drivers, trans-impedance amplifiers, and the like for performing functions such as controlling high-frequency signaling of the PIC chip 110.

The second wiring structure 122 may include a second wiring pattern 1221 and a second wiring insulating layer 1222 surrounding the second wiring pattern 1221. The second wiring pattern 1221 may include second wiring lines 1221_L extending in the horizontal direction and second wiring vias 1221_V extending from the second wiring lines 1221_L in the vertical direction (Z direction). The second wiring pattern 1221 may be electrically connected to the plurality of individual devices and lower pads 128.

In some embodiments, the EIC chip 120 may be located on the PIC chip 110 such that the active surface of the second substrate 121 faces the PIC chip 110. For example, the EIC chip 120 may be located on the PIC chip 110 in a face down manner.

In some embodiments, a bonding layer BL may be located between the EIC chip 120 and the PIC chip 110. The bonding layer BL may include bonding pads BP and a bonding insulating layer BD surrounding the bonding pads BP. For example, the EIC chip 120 may be electrically connected to the PIC chip 110 due to the bonding layer BL located between the EIC chip 120 and the PIC chip 110.

In some embodiments, the bonding pads BP of the bonding layer BL may be formed by the upper pads 117 of the PIC chip 110 and the lower pads 128 of the EIC chip 120, which are diffusion bonded due to heat. In a process of forming the bonding pads BP, the bonding insulating layer BD may be formed since an insulating layer surrounding the upper pads 117 of the PIC chip 110 and an insulating layer surrounding the lower pads 128 of the EIC chip 120 may also be diffusion bonded due to heat.

For example, the EIC chip 120 may be electrically connected to the PIC chip 110 through hybrid bonding. However, the embodiments are not limited thereto. The EIC chip 120 may be electrically connected to the PIC chip 110 due to connection terminals such as solder balls or adhesive films such as anisotropic films (ACF) and non-conductive films (NCF).

The connector 130 may be located above the PIC chip 110. For example, the connector 130 may be located above the optical guide unit 113_T of the PIC chip 110. The connector 130 may be spaced apart from the EIC chip 120 in the horizontal direction. The connector 130 may include a body 131 and the second waveguide 132. The second waveguide 132 may extend from an upper surface to a lower surface of the body 131. The connector 130 may be described as a package external connector, which connects the package 10 to an external device such as optical fiber module 400.

For example, the second waveguide 132 may be located above the optical guide unit 113_T. For example, a lens 420_R of the optical fiber 420 may be located above the second waveguide 132. For example, one end of the second waveguide 132 may face the lens 420_R of the optical fiber 420 and the other end of the second waveguide 132 may face the optical guide unit 113_T.

In some embodiments, a refractive index of the second waveguide 132 may be greater than that of the body 131. The optical signal OS transmitted from the optical fiber 420 or the PIC chip 110 to the second waveguide 132 may move along the second waveguide 132. The optical signal OS moving along the second waveguide 132 may be totally reflected at a boundary between the second waveguide 132 and the body 131 due to the difference in the refractive indices of the second waveguide 132 and the body 131.

For example, a component of the body 131 of the connector 130 may be glass, and the second waveguide 132 of the connector 130 may be formed to have a refractive index greater than that of glass through an ion exchange process. However, the embodiments are not limited thereto. For example, the body 131 of the connector 130 may include silicon oxide and the second waveguide 132 may include silicon.

The connector 130 may include an engagement groove 131_H1, also described as an engagement receptacle. The engagement groove 131_H1 may extend inward from the upper surface of the body 131 of the connector 130. The engagement groove 131_H1 may be spaced apart from the second waveguide 132 in the horizontal direction. The engagement groove 131_H1 may have a circular shape from a plan view, but in other embodiments may have other shapes. One or more engagement grooves 131_H1 may be included.

The optical fiber module 400 may include a frame 410 and a plurality of the optical fibers 420 attached to the frame 410. The frame 410 may be detachably coupled to the connector 130. Terminal ends of optical fibers may be housed in the optical fiber module 400, and so the optical fiber module 400 may also be described as an optical fiber terminal connector.

When connected, the optical fibers 420 may be located above the second waveguide 132. The optical fibers 420 may overlap the second waveguide 132 in the vertical direction (Z direction). For example, the optical fibers 420, the second waveguide 132, and the optical guide unit 113_T may be located on a straight line in the vertical direction (Z direction). The optical signal OS output from the optical fibers 420 may be input into the second waveguide 132. A plurality of second waveguides may be used to transfer the signals output from a plurality of optical fibers 420 to a plurality of first waveguides 113 through a plurality of respective optical guide units 113_T. For example, though FIG. 3 shows only one example optical fiber 420, second waveguide 132, optical guide unit 113_T, and first waveguide 113, a plurality of each of these may be used to transfer signals to and from the chip structure, as can be seen for example in FIG. 2.

The frame 410 may include a protrusion 410_E protruding from a lower surface of the frame 410 to the outside. The protrusion 410_E of the frame 410 may remain inserted into the engagement groove 131_H1 of the connector 130, thereby maintaining the optical fiber module 400 coupled to the connector 130. The protrusion 410_E may have a circular shape from a plan view, but in other embodiments may have other shapes. One or more protrusions 410_E may be included to match the number of engagement grooves 131_H1.

In some embodiments, the connector 130 may further include an inner groove 131_SN, and the frame 410 may further include a coupling hook 410_SN corresponding to the inner groove 131_SN. The coupling hook 410_SN, also described as a coupling ring, coupling protrusion, rib, or coupler, may be inserted into the inner groove 131_SN when the protrusion 410_E of the frame 410 is inserted into the engagement groove 131_H1 of the connector 130.

For example, the inner groove 131_SN of the connector 130 may be located on a side surface defining the engagement groove 131_H1 of the connector 130. The coupling hook 410_SN of the frame 410 may be located on a side surface of the protrusion 410_E.

In some embodiments, the coupling hook 410_SN of the frame 410 may be coupled to the inner groove 131_SN of the connector 130 in a snap-fit manner. For example, the coupling hook 410_SN may be inserted into or separated from the inner groove 131_SN using elasticity of the coupling hook 410_SN.

In some embodiments, the optical fiber module 400 may further include an operation button allowing a user to control movement of the coupling hook 410_SN by applying pressure to the operation button. Using the operation button, the user may separate the coupling hook 410_SN from the inner groove 131_SN and thus separate the optical fiber module 400 from the connector 130. For example, the coupling hook 410_SN may be movable based on a mechanical operation button or other control device to allow it to retract or expand horizontally to fill and attach to the inner groove 131_SN or to release from the inner groove 131_SN.

This is only illustrative and the way that the optical fiber module 400 is detachably connected to the connector 130 is not limited to the embodiment described above. The optical fiber module 400 may be detachably connected to the connector 130 in various known ways.

In some embodiments, the connector 130 may be attached onto the PIC chip 110 through the transparent adhesive layer TL. The optical fiber module 400 may be detachably coupled to the engagement groove 131_H1 of the connector 130. Since the optical fiber module 400 may be detachable from the chip structure 100 through the connector 130, the optical fiber module 400 may be easily replaced.

The chip structure 100 may further include a molding layer EL. The molding layer EL may be disposed above the PIC chip 110 and surround the EIC chip 120 and the connector 130. The molding layer EL may protect the EIC chip 120 and the connector 130 from the outside.

In some embodiments, an upper surface of the molding layer EL may be coplanar with an upper surface of the EIC chip 120 and an upper surface of the connector 130. The upper surface of the EIC chip 120 may be exposed to the outside and may thus facilitate dissipation of heat generated in the EIC chip 120. The engagement groove 131_H1 of the connector 130 may be exposed to the outside so that the optical fiber module 400 may be coupled to the connector 130.

For example, the molding layer EL may include epoxy resin, polyimide resin, and the like. The molding layer EL may include, for example, an epoxy molding compound (EMC).

The chip structure 100 may further include a polishing stop film PS. The polishing stop film PS may be located between the molding layer EL and the connector 130, between the molding layer EL and the EIC chip 120, and between the molding layer EL and the PIC chip 110. For example, the molding layer EL may be spaced apart from the PIC chip 110, the EIC chip 120, and the connector 130 with the polishing stop film PS therebetween.

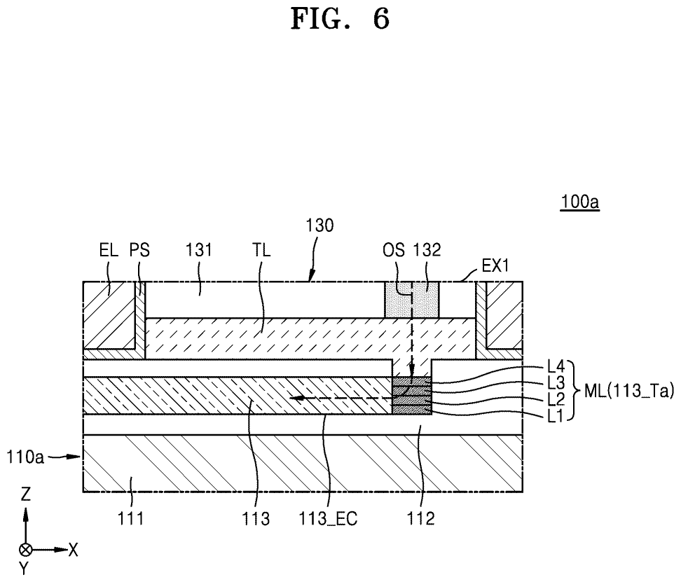

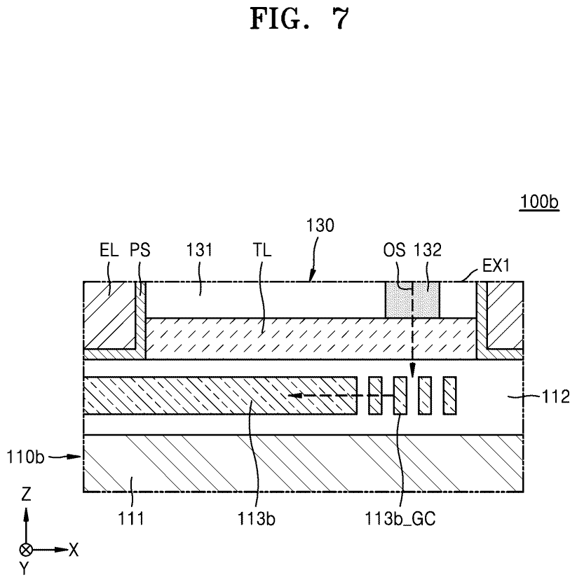

FIG. 6 is an enlarged view schematically illustrating a portion of a chip structure 100a according to an embodiment. FIG. 7 is an enlarged view schematically illustrating a portion of a chip structure 100b according to an embodiment.

Most of components forming the chip structures 100a and 100b described below and materials forming the components are substantially the same as or similar to those described above with reference to FIG. 4. Therefore, for convenience of description, the description focuses on the differences between the chip structures 100a and 100b of FIGS. 6 and 7 and the chip structure 100 of FIG. 4.

Referring to FIG. 6, the chip structure 100a may include a PIC chip 110a. The PIC chip 110a may include a first substrate 111, a first wiring structure 112, a first waveguide 113, and an optical guide unit 113_Ta.

A connector 130 may be attached onto the PIC chip 110a. An optical signal OS emitted from a second waveguide 132 of the connector 130 may be input into the first waveguide 113 of the PIC chip 110a through the optical guide unit 113_Ta.

For example, the first waveguide 113 may include an edge coupler 113_EC. The edge coupler 113_EC may be located at an end adjacent to the optical guide unit 113_Ta among both ends of the first waveguide 113. The PIC chip 110a may transmit and receive a multi-wavelength optical signal OS through the edge coupler 113_EC.

The optical guide unit 113_Ta of the PIC chip 110a may include a plurality of layers ML. For example, since each of the plurality of layers ML may have a different refractive index, the optical signal OS may be refracted each time the optical signal OS passes through each of the plurality of layers ML.

For example, the optical signal OS incident to the optical guide unit 113_Ta may be refracted each time the optical signal OS passes through a single layer. For example, the optical signal OS incident to an upper surface of the optical guide unit 113_Ta in the vertical direction (Z direction) may be refracted while passing through the plurality of layers ML and then emitted from a side surface of the optical guide unit 113_Ta in the horizontal direction.

In some embodiments, among the plurality of layers ML, layers closer to the first substrate 111 may have smaller refractive indices. Among the plurality of layers ML, layers positioned further below in the vertical direction (Z direction) may have smaller refractive indices. For example, the plurality of layers ML may include a first layer L1, a second layer L2, a third layer L3, and a fourth layer L4. A refractive index of the first layer L1 may be less than that of the second layer L2, the refractive index of the second layer L2 may be less than that of the third layer L3, and the refractive index of the third layer L3 may be less than that of the fourth layer L4.

In some embodiments, the optical guide unit 113_Ta may include a prism. For example, the optical signal OS may be refracted through the prism of the optical guide unit 113_Ta. Accordingly, the optical signal OS incident to one surface among an upper surface and side surfaces of the prism may be emitted to another surface. The way that the optical guide unit 113_Ta refracts the optical signal OS is not limited to those described above.

Referring to FIG. 7, a PIC chip 110b of the chip structure 100b may include a first waveguide 113b. The first waveguide 113b may further include a grating coupler 113b_GC. The grating coupler 113b_GC may be located at an end of the first waveguide 113b. For example, the grating coupler 113b_GC may be located below a second waveguide 132.

For example, the PIC chip 110b may receive an optical signal OS from the second waveguide 132 or transmit the optical signal OS to the second waveguide 132 through the grating coupler 113_GC without an optical guide unit.

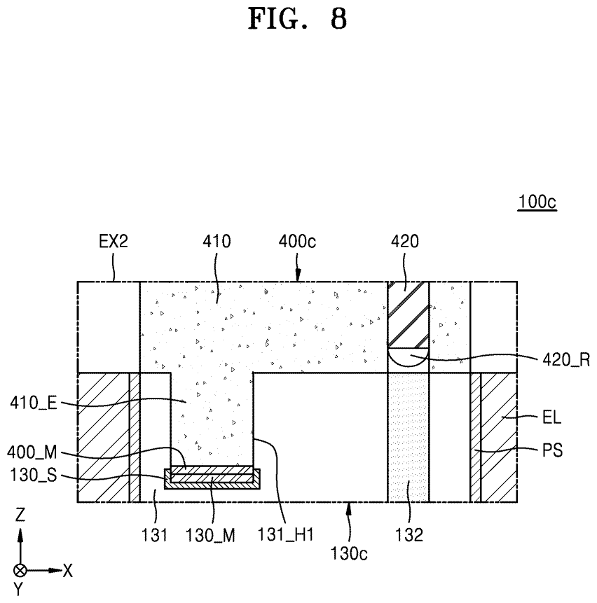

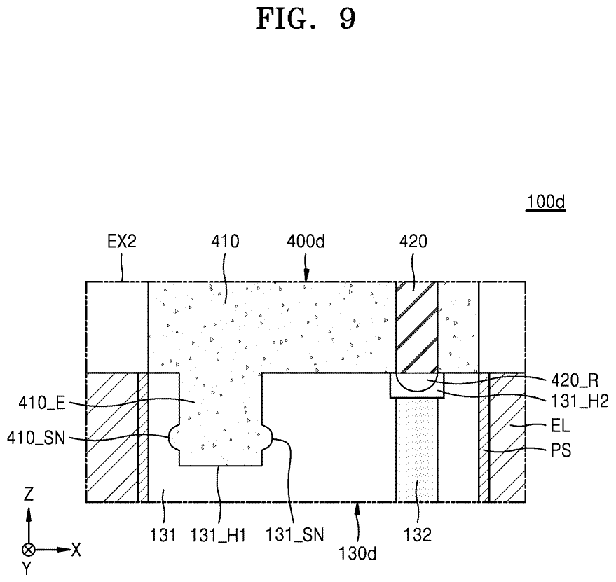

FIG. 8 is an enlarged view schematically illustrating a portion of a chip structure 100c and an optical fiber module 400c according to an embodiment. FIG. 9 is an enlarged view schematically illustrating a portion of a chip structure 100d and an optical fiber module 400d according to an embodiment.

Most of components forming the chip structures 100c and 100d described below and materials forming the components are substantially the same as or similar to those described above with reference to FIG. 5. Therefore, for convenience of description, the description focuses on the differences between the chip structures 100c and 100d of FIGS. 8 and 9 and the chip structure 100 of FIG. 5.

Referring to FIG. 8, a connector 130c of the chip structure 100c may include a first magnet 130_M. The first magnet 130_M may be located in an engagement groove 131_H1 of the connector 130c. The optical fiber module 400c may include a first metal member 400_M sticking to a magnet. The first metal member 400_M may be located in a protrusion 410_E of the optical fiber module 400c.

The first metal member 400_M and the first magnet 130_M may be located such that the first metal member 400_M may contact the first magnet 130_M when the protrusion 410_E is inserted into the engagement groove 131_H. In some embodiments, the first magnet 130_M may be located on a bottom surface defining the engagement groove 131_H1 of the connector 130c and the first metal member 400_M may be located on a lower surface of the protrusion 410_E. In some embodiments, the first magnet 130_M may be located at a side wall defining the engagement groove 131_H1 and the first metal member 400_M may be located at a side wall of the protrusion 410_E.

In some embodiments, the connector 130c may further include a shield 130_S. The shield 130_S may be located on the bottom surface and side surfaces defining the engagement groove 131_H1 of the connector 130c. For example, the shield 130_S may be in contact with the first magnet 130_M of the connector 130c. For example, the shield 130_S may be located between the first magnet 130_M and a body 131. The shield 130_S may suppress a magnetic field of the first magnet 130_M from being transmitted to the surroundings. Accordingly, a phenomenon of noise occurrence in optical or electrical signals may be suppressed.

In some embodiments, a metal member sticking to a magnet may be located in the engagement groove 131_H1 of the connector 130c and a magnet may be located in the protrusion 410_E of the optical fiber module 400c. For example, the protrusion 410_E of the optical fiber module 400c may be detachably fixed into the engagement groove 131_H1 of the connector 130c through the first metal member 400_M and the first magnet 130_M. Generally speaking, in the above embodiments, the connector 130 may include a socket and the optical fiber module 400 may include a plug that fits into and affixes to the socket (e.g., via a magnet, rib, or other mechanism).

Referring to FIG. 9, a connector 130d of the chip structure 100d may include a first groove 131_H2. The first groove 131_H2 may extend from an upper surface of a body 131 of the connector 130d into the body 131. For example, the first groove 131_H2 may be located on a second waveguide 132 of the connector 130d. The second waveguide 132 may extend from a bottom surface defining the first groove 131_H2 to a lower surface of the body 131.

In some embodiments, a depth of the first groove 131_H2 may differ from that of an engagement groove 131_H1. The depth of the first groove 131_H2 may be less than that of the engagement groove 131_H1. For example, a vertical level of the bottom surface of the first groove 131_H2 may be greater than a vertical level of the engagement groove 131_H1. As used herein, the vertical level refers to a distance from a lower surface of the PIC chip 110 (see FIG. 3) when the optical fiber module 400d is fully engaged with the connector 130d.

In some embodiments, though not shown in FIG. 9, a portion of an optical fiber 420 of the optical fiber module 400d may protrude from a lower surface of a frame 410 of the optical fiber module 400d to the outside. For example, a vertical level of the lowermost end of the optical fiber module 400d may be lower than a vertical level of the lower surface of the frame 410. In this case, or in the case as shown in FIG. 9, A lens 420_R of the optical fiber module 400d may be located outside the frame 410. In some embodiments, when the optical fiber module 400d is coupled to the connector 130d, a portion of the optical fiber 420 protruding downward from the lower surface of the frame 410 may be located in the first groove 131_H2.

The optical fiber module 400d in which the portion of the optical fiber 420 protrudes to or beyond the lower surface of the frame 410 may be coupled to the connector 130d through the first groove 131_H2. In addition, since the portion of the optical fiber 420 and/or the lens 420_R may be inserted into the first groove 131_H2, coupling reliability between the optical fiber module 400d and the connector 130d may be improved.

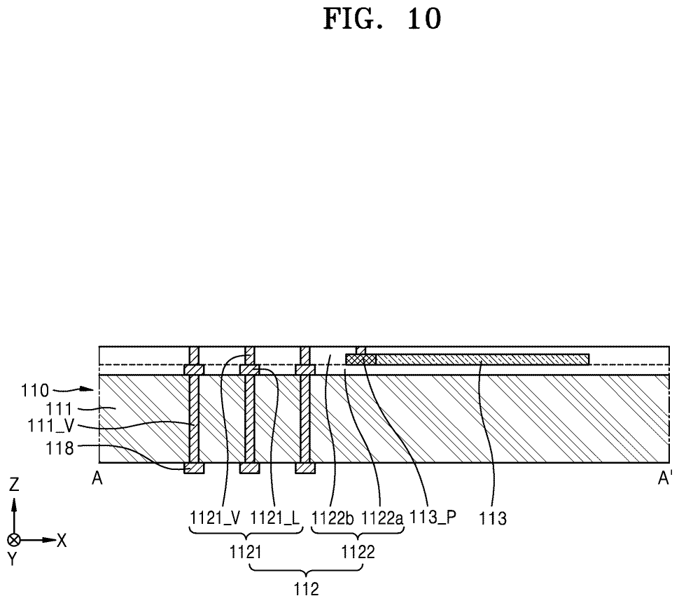

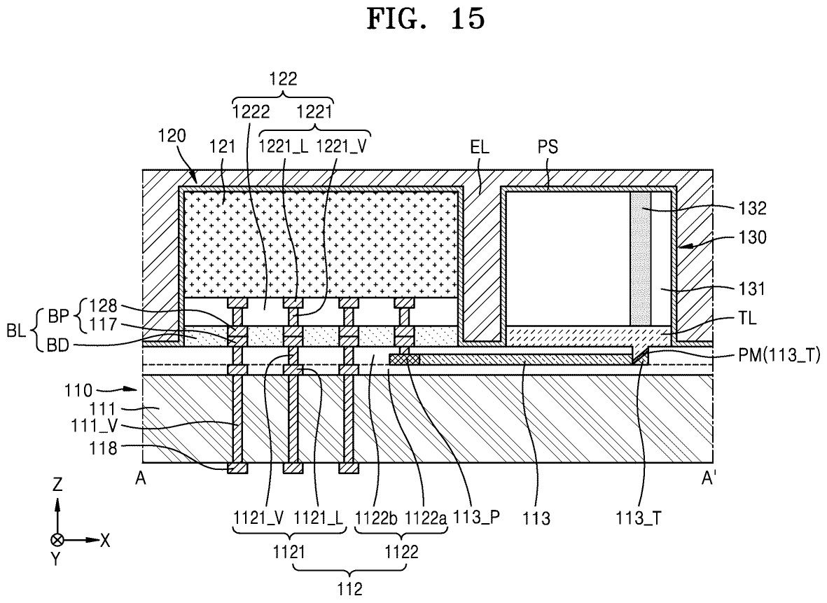

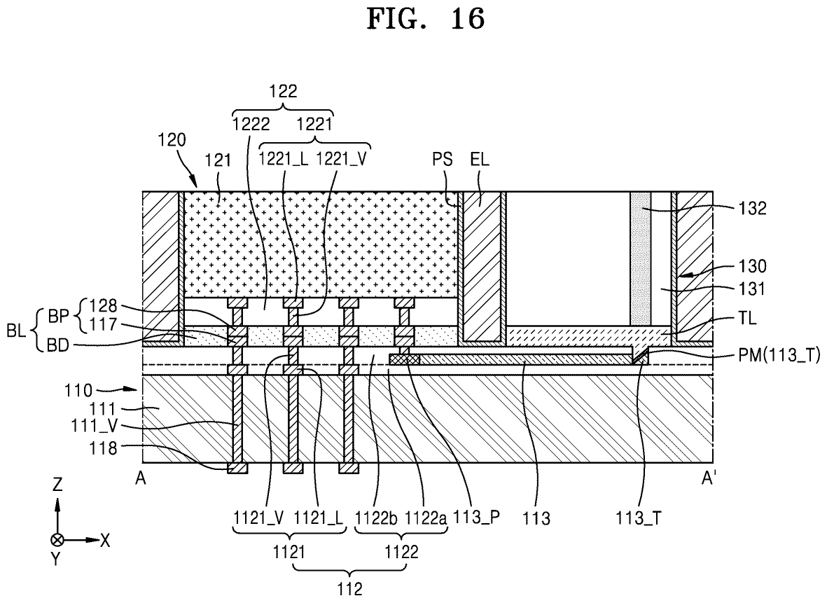

FIGS. 10 to 18 are diagrams illustrating a manufacturing method of the chip structure 100 in a process sequence, according to an embodiment.

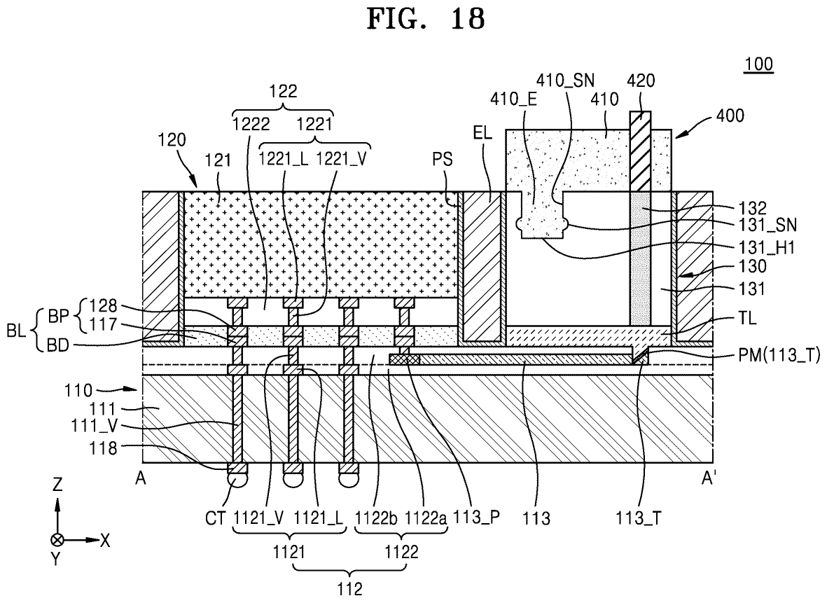

Specifically, FIGS. 10 to 17 illustrate cross-sectional views of the chip structure 100 of FIG. 2 taken along line A-A′ of FIG. 2 in order of procedures of the manufacturing method of the chip structure 100. FIG. 18 is a cross-sectional view illustrating the chip structure 100 to which the optical fiber module 400 is coupled.

Most of components forming the chip structure 100 described below and materials forming the components are substantially the same as or similar to those described above with reference to FIG. 2. Therefore, for convenience of description, repeated descriptions with the chip structure 100 of FIG. 2 are omitted.

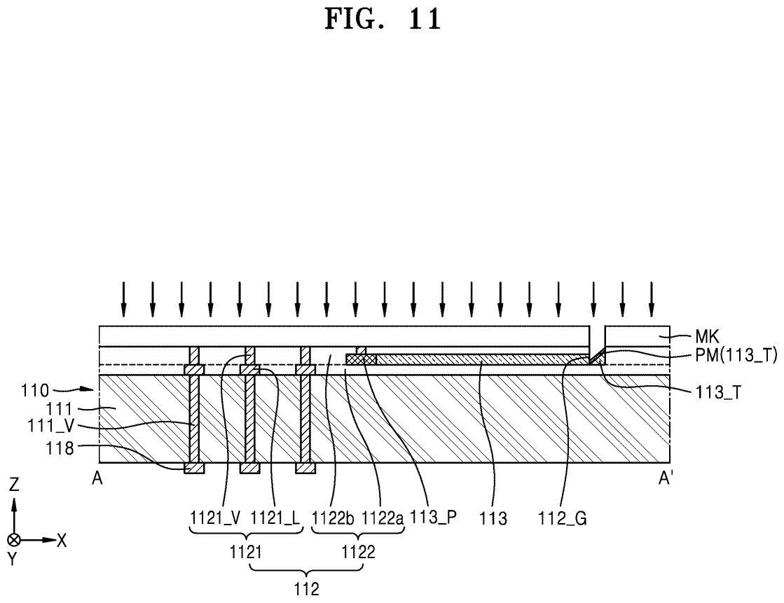

Referring to FIGS. 10 and 11, a PIC chip 110 may be prepared and an optical guide unit 113_T may be formed on the PIC chip 110. The description is provided on the assumption that the optical guide unit 113_T includes at least one mirror PM.

The PIC chip 110 may include a first substrate 111, a first wiring structure 112, and a first waveguide 113. The first waveguide 113 and the first wiring structure 112 may be located on an upper surface of the first substrate 111. In some embodiments, the first waveguide 113 may be located in the first wiring structure 112.

The first waveguide 113 and the first wiring structure 112 may be patterned by positioning a photo mask MK on an upper surface of the PIC chip 110 and performing a photolithography process and etching process. For example, a portion of the first wiring structure 112 may be removed through the photolithography process and etching process and a groove 112_G extending from an upper surface of the first wiring structure 112 to the first waveguide 113 may thus be formed.

The at least one mirror PM may be formed by processing a nanoimprint process or ion implantation process to an upper surface of the first waveguide 113 that is located under the groove 112_G of the first wiring structure 112 and patterned by the photolithography process and etching process. Accordingly, a component of the at least one mirror PM may be the same as a component of the first waveguide 113.

For example, a portion of the first waveguide 113, which has been patterned and has a surface that has undergone the nanoimprint process, may be referred to as the optical guide unit 113_T. However, the optical guide unit 113_T may be formed to reflect an optical signal and also to refract the optical signal.

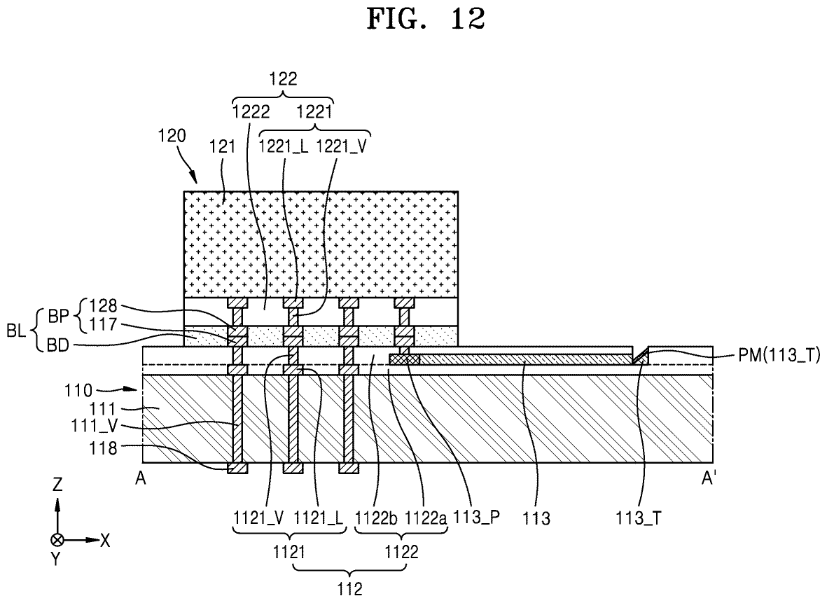

Referring to FIG. 12, an EIC chip 120 may be attached onto the PIC chip 110.

The EIC chip 120 may include a second substrate 121 and a second wiring structure 122. The EIC chip 120 may be attached onto the PIC chip 110 in a face down manner such that the second wiring structure 122 of the EIC chip 120 faces the PIC chip 110.

In some embodiments, the EIC chip 120 may be coupled to the PIC chip 110 by hybrid bonding. For example, the EIC chip 120 may be electrically connected to the PIC chip 110 due to a bonding layer BL located between the EIC chip 120 and the PIC chip 110. However, a connecting method between the EIC chip 120 and the PIC chip 110 is not limited thereto.

For example, the bonding layer BL may include bonding pads BP and a bonding insulating layer BD. The bonding pads BP may be formed since lower pads 128 of the EIC chip 120 and upper pads 117 of the PIC chip 110 are diffusion bonded due to heat.

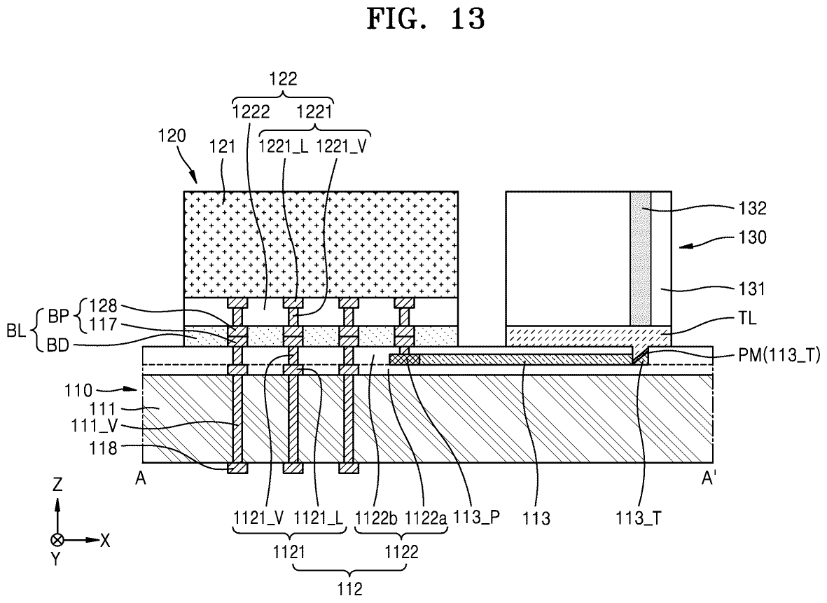

Referring to FIG. 13, a connector 130 may be attached onto the PIC chip 110.

The connector 130 may include a body 131 and a second waveguide 132 extending from an upper surface to a lower surface of the body 131. For example, the connector 130 may be attached onto the PIC chip 110 by a transparent adhesive layer TL through which an optical signal is transmitted. The second waveguide 132 of the connector 130 may extend in the vertical direction (Z direction) and may be located above the optical guide unit 113_T. The optical signal emitted from the second waveguide 132 may pass through the transparent adhesive layer TL and may be incident to the optical guide unit 113_T. In some embodiments, the transparent adhesive layer TL may be located in the groove 112_G of the first wiring structure 112. The transparent adhesive layer TL maybe formed of a transparent adhesive material, such as an epoxy material. For example, the transparent adhesive layer TL may include one or more of polyethylene terephthalate (PET), polyimide (PI), polypropylene (PP), polycarbonate (PC), acrylic-based resin, and silicone-based polymers.

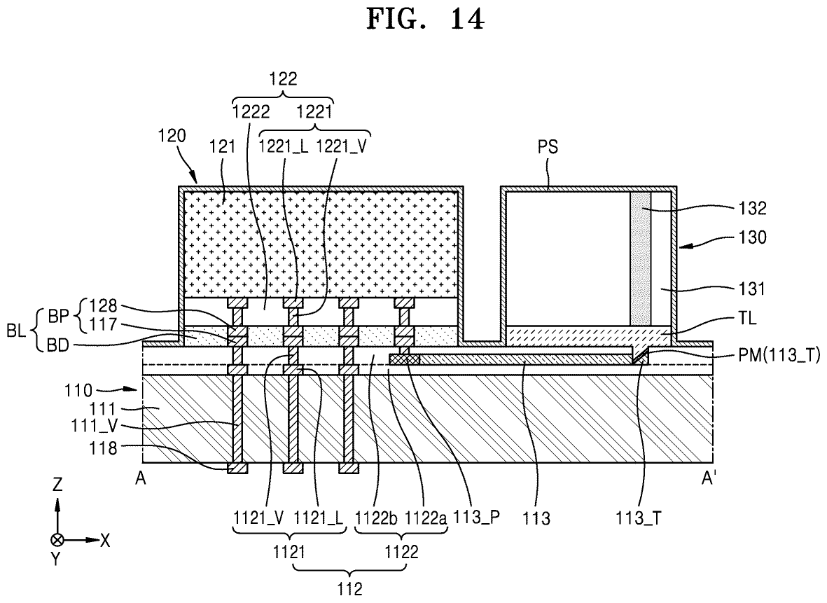

Referring to FIGS. 14 to 16, a polishing stop film PS and a molding layer EL may be formed on the resultant structure of FIG. 13.

The polishing stop film PS may be formed on an upper surface of the resultant structure of FIG. 13. The polishing stop film PS may cover a portion of the upper surface of the PIC chip 110, an upper surface and side surfaces of the EIC chip 120, and an upper surface and side surfaces of the connector 130, and may be conformally and continuously formed on these components, without any gaps therebetween. The polishing stop film PS may include, for example, one or more of silicon nitride (SiN), silicon dioxide (SiO₂), silicon carbide (SiC), and silicon carbonitride (SiCN).

Then, the molding layer EL may be formed to cover the EIC chip 120 and the connector 130 above the PIC chip 110. The molding layer EL may be formed on the polishing stop layer PS and spaced apart from the PIC chip 110, the EIC chip 120, and the connector 130 with the polishing stop layer PS therebetween.

Then, an upper portion of the molding layer EL may be removed to expose an upper surface of the polishing stop layer PS and the exposed upper surface of the polishing stop layer PS may be removed through an etching process. Accordingly, the upper surface of the EIC chip 120 may be coplanar with an upper surface of the molding layer EL and the upper surface of the connector 130. The polishing stop layer EL (e.g., a continuously-formed portion of the polishing stop layer EL without any gaps therein) located between the PIC chip 110 and the molding layer EL, between the EIC chip 120 and the molding layer EL, and between the connector 130 and the molding layer EL may not be removed by the etching process since the polishing stop layer El is not exposed to the outside.

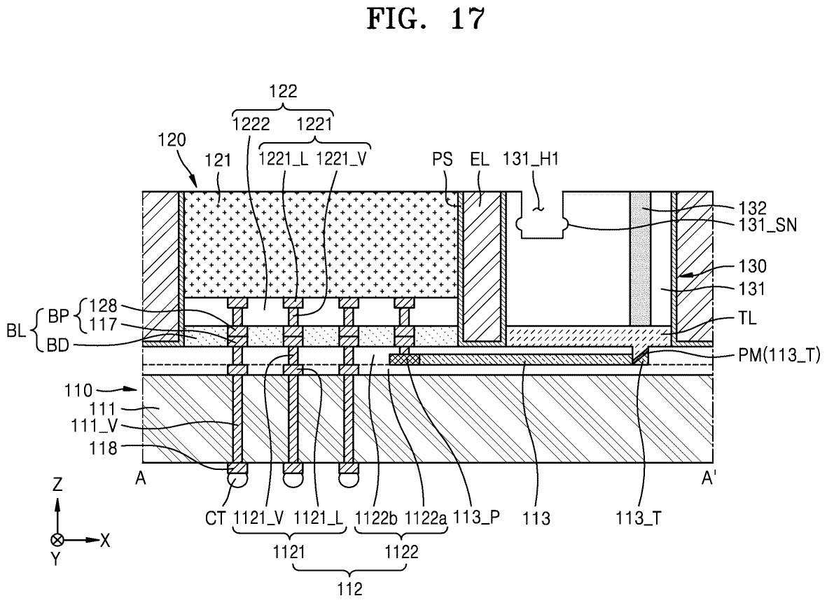

Referring to FIG. 17, the chip structure 100 may be manufactured by forming an engagement groove 131_H1, also described as a socket, in the upper surface of the connector 130.

In some embodiments, the engagement groove 131_H1 extending inward from the upper surface of the connector 130 may be formed in the connector 130 by performing a laser drilling process. The connector 130 may be detachably coupled to an optical fiber module 400 through the engagement groove 131_H1. The engagement groove 131_H1 of the connector 130 may not overlap the optical guide unit 113_T in the vertical direction (Z direction). Then, connection terminals CT may be formed on the lower pads 118 of the PIC chip 110 so as to attach the chip structure 100 to the package substrate 200 (see FIG. 1).

Referring to FIG. 18, the optical fiber module 400 may be detachably coupled to the chip structure 100.

The optical fiber module 400 may include a frame 410 and an optical fiber 420 attached to the frame 410. The frame 410 may include a protrusion 410_E formed to be inserted into the engagement groove 131_H1 of the connector 130.

In some embodiments, the optical fiber module 400 may be coupled to the chip structure 100 without a separate adhesive material. For example, the frame 410 of the optical fiber module 400 may further include a coupling hook 410_SN, and the connector 130 of the chip structure 100 may further include an inner groove 131_SN. The optical fiber module 400 may be coupled to the chip structure 100 in a snap-fit manner. In other embodiments, a magnet or other affixing mechanism may be used.

Since the optical fiber module 400 may be detached from the chip structure 100, a repair of the semiconductor package 10 (see FIG. 1) including the chip structure 100 may be easy because the optical fiber module 400 may be replaced if a failure occurs in the optical fiber 420.

While the inventive concept has been particularly shown and described with reference to embodiments thereof, it will be understood that various changes in form and details may be made therein without departing from the spirit and scope of the following claims.

1. A chip structure comprising:
an optical integrated circuit chip including a first waveguide extending in a horizontal direction and an optical guide unit;
an electronic integrated circuit chip on the optical integrated circuit chip; and
a connector above the optical integrated circuit chip and including a body, a second waveguide extending from an upper surface to a lower surface of the body, and an engagement groove extending inward from the upper surface of the body;
wherein the first waveguide includes an edge coupler at an end adjacent to the optical guide unit among two ends of the first waveguide, and
wherein the optical guide unit is configured to transfer signals between the first waveguide and the second waveguide.

2. The chip structure of claim 1, wherein:
the optical guide unit includes at least one mirror, and
the at least one mirror is positioned such that the optical signal output from one waveguide between the first waveguide and the second waveguide is reflected and is incident to the other waveguide.

3. The chip structure of claim 1, wherein the optical guide unit includes a plurality of layers having different refractive indices.

4. The chip structure of claim 3, wherein, among the plurality of layers, layers positioned further below in a vertical direction have smaller refractive indices.

5. The chip structure of claim 1, wherein a refractive index of the second waveguide of the connector is greater than a refractive index of the body of the connector.

6. The chip structure of claim 5, wherein a component of the body of the connector includes glass.

7. The chip structure of claim 1, wherein:
the connector includes an additional groove recessed inward from the upper surface of the body,
the additional groove is above the second waveguide, and
the engagement groove is spaced apart from the second waveguide.

8. The chip structure of claim 7, wherein a depth of the engagement groove is greater than a depth of the additional groove.

9. The chip structure of claim 1, further comprising a molding layer above the optical integrated circuit chip and surrounding the electronic integrated circuit chip and the connector.

10. The chip structure of claim 9, wherein an upper surface of the electronic integrated circuit chip is coplanar with an upper surface of the molding layer and an upper surface of the connector.

11. The chip structure of claim 1, further comprising an optical fiber module including a frame formed to be detachably coupled to the engagement groove of the connector and an optical fiber attached to the frame.

12. The chip structure of claim 11, wherein:
the frame includes a protrusion on a lower surface of the frame and a coupling hook on a side surface of the protrusion, and
the connector further includes an inner groove at a side wall that defines the engagement groove of the connector and formed so that the coupling hook is inserted to the inner groove.

13. A chip structure comprising:
an optical integrated circuit chip including a first waveguide extending in a horizontal direction;
an electronic integrated circuit chip on the optical integrated circuit chip;
a connector above the optical integrated circuit chip and including a body, a second waveguide extending from an upper surface to a lower surface of the body, and an engagement groove extending inward from the upper surface of the body;
a molding layer above the optical integrated circuit chip and surrounding the electronic integrated circuit chip and the connector; and
a polishing stop film between the molding layer and the connector, between the molding layer and the electronic integrated circuit chip, and between the molding layer and the optical integrated circuit chip.

14. The chip structure of claim 13, wherein the polishing stop film is a continuously formed layer between the molding layer and the connector, between the molding layer and the electronic integrated circuit chip, and between the molding layer and the optical integrated circuit chip.

15. The chip structure of claim 13, further comprising:
a inter-waveguide router configured to transfer signals between the first waveguide and the second waveguide.

16. The chip structure of claim 13, wherein an upper surface of the connector is coplanar with an upper surface of the molding layer and an upper surface of the electronic integrated circuit chip.

17. (canceled)

18. The chip structure of claim 13, wherein the connector further includes an inner groove recessed from a side wall defining the engagement groove into the connector.

19. A semiconductor package comprising:
a package substrate;
a semiconductor chip on the package substrate;
a chip structure located on the package substrate and including an optical integrated circuit chip, an electronic integrated circuit chip on the optical integrated circuit chip, and a connector above the optical integrated circuit chip; and
an optical fiber module including a frame formed to be detachably coupled to the connector of the chip structure and an optical fiber attached to the frame,
wherein the optical integrated circuit chip of the chip structure includes a first waveguide extending in a horizontal direction on an upper surface of the optical integrated circuit chip, and
the connector of the chip structure further includes a second waveguide extending in a vertical direction.

20. (canceled)

21. The semiconductor package of claim 19, wherein:
the optical integrated circuit chip further includes an optical guide unit on a side of the first waveguide and configured to transfer an optical signal between the first waveguide and the second waveguide, and
the first waveguide includes an edge coupler located at an end adjacent to the optical guide unit among two ends of the first waveguide.

22. The semiconductor package of claim 19, wherein:
the chip structure further includes a molding layer and a polishing stop film,
the molding layer is located above the optical integrated circuit chip and surrounds the electronic integrated circuit chip and the connector, and
the polishing stop film is between the molding layer and the connector, between the molding layer and the electronic integrated circuit chip, and between the molding layer and the optical integrated circuit chip.
